(19) United States
(12) Patent Application Publication
(10) Pub. No.: US 2026/0329193 A1
(43) Pub. Date: Oct. 22, 2026

(54) ASSEMBLY FOR SEMICONDUCTOR TECHNOLOGY, AND DEVICE FOR SEMICONDUCTOR TECHNOLOGY

(71) Applicant: Carl Zeiss SMT GmbH, Oberkochen (DE)

(72) Inventors: Johannes Kruis, Oberkochen (DE); Christian Werner, Beek en Donk (NL); Tobias Hegele, Aachen (DE); Walter Loch, Veghel (NL); Bob Bastiaan Max Mutsaers, Berkel-Enscho (NL); Wouter Doppenberg, 's-Hertogenbosch (NL); Roland Gischa, Bibertal (DE); Sebastian Henseler, Aalen (DE); Dietmar Duerr, Dettingen (DE); Paul Martinus van den Hoogenhof, Eindhoven (NL)

(21) Appl. No.: 19/468,050

(22) Filed: Feb. 3, 2026

Related U.S. Application Data
(63) Continuation of application No. PCT/EP2024/070397, filed on Jul. 18, 2024.

(30) Foreign Application Priority Data
Aug. 9, 2023 (DE) 102023207631.4

(51) Int. Cl. G03F 7/00; G01N 21/956; G03F 1/84

(52) U.S. Cl. CPC G03F 7/70816; G01N 21/956; G03F 1/84; G03F 7/70266; G03F 7/70833; G01N 2021/95676

(57) ABSTRACT

Disclosed is an assembly for semiconductor technology comprising a module and a module frame, wherein the module is connected to the module frame via a bearing element and is positioned by the bearing element with respect to the module frame and the connection comprises a clamping device, which prevents the module from lifting off the module frame. The bearing element has a clamping force element for transmitting a clamping force caused by the clamping device and a positioning element for positioning the module with respect to the module frame.

### CROSS REFERENCE TO RELATED APPLICATIONS

The present application is a continuation of and claims benefit under 35 U.S.C. § 120 from PCT Application No. PCT/EP 2024/070397, filed on Jul. 18, 2024, which claims priority from German Application No. 10 2023 207 631.4, filed on Aug. 9, 2023. The content of each of these earlier applications are incorporated by reference herein.

### TECHNICAL FIELD

This disclosure relates to an assembly for semiconductor technology and to a device for semiconductor technology, for example a mask inspection device or a projection exposure apparatus.

### BACKGROUND

Projection exposure apparatuses for semiconductor lithography are used for producing extremely fine structures, in particular on semiconductor components or other microstructured components. The functional principle of said apparatuses is based on the production of extremely fine structures down to the nanometer range by way of generally reducing imaging of structures on a mask, with a so-called reticle, on an element to be structured, such as, for example, a wafer, that is provided with photosensitive material. The minimum dimensions of the structures produced are directly dependent on the wavelength of the light used, the so-called used light. In an emission wavelength range referred to as the DUV range, the light sources used have wavelengths of 100 nm to 300 nm, while light sources with an emission wavelength of the order of a few nanometers, for example between 1 nm and 120 nm, in particular of the order of 13.5 nm, have increasingly being used in recent times. The described emission wavelength range is also referred to as the EUV range.

Optical elements such as for example lens elements, but also (especially in the field of EUV lithography) mirrors, are used to illuminate the structures and in particular to image them, and their so-called optical effective surfaces are impinged on by used light during the customary operation of the associated apparatus. Deviations of the optical effective surfaces from an optimal target position and target shape have a huge effect on the quality of the imaging and thus on the quality of the components produced.

This problem is typically addressed by the optical elements used being designed to be movable or deformable in order to enable the correction of the aforementioned imaging aberrations during the operation of the projection exposure apparatus. The optical elements are usually arranged in receptacles of optical modules, the latter being mounted on module frames, which in turn can be movably mounted on an optics frame via actuators, as described further above, and can thereby be positioned at a predetermined position.

For the accurate alignment of the optical modules on the module holder, a statically determined or quasi-static mounting is preferred, which is formed for example by three so-called bipods, i.e. two-legged supports, each having a linking point at the optical module and two mounting points each on the module holder. The bipods with the optical module usually only lie on the mounting points of the module holder, so that the optical module must be secured against lifting off the mounting points, for example by clamping elements. However, in the solutions known from the prior art, the force flow of the forces applied by the clamping elements passes through the bipods, whereby the latter can be deformed. The resultant mechanical stresses in the bipods can be transmitted to the optical module and subsequently to the optical element as well. This has the disadvantage that the position of the optical module with respect to the module holder can change and/or the optical element with its optical effective surface can be deformed, which can have a negative effect on the imaging quality of the associated projection exposure apparatus.

A further disadvantage of the solutions known from the prior art is that after a possible replacement of the optical module during operation, both the position of the new optical module and the deformation of the corresponding optical effective surface may generally deviate significantly from the values of the original module, and so the increasing demands on imaging quality from generation to generation can no longer be sufficiently ensured after the replacement.

### SUMMARY

Embodiments of the present disclosure provide a device which eliminates the above-described disadvantages of the prior art.

In general, in one aspect, disclosed is an assembly for semiconductor technology including a module and a module frame, wherein the module is connected to the module frame via a bearing element and is positioned by the bearing element with respect to the module frame. The connection comprises a clamping device, which prevents the module from lifting off the module frame.

The bearing element has a clamping force element for transmitting a clamping force caused by the clamping device and a positioning element for positioning the module with respect to the module frame. This has the advantage that the high clamping force due to the purpose has no or almost no influence on the positioning of the module. The clamping force is designed in such a way that it is possible to reliably avoid the module lifting off the module frame under predetermined loads. The loads concern not just the loads occurring during operation, but in particular the significantly higher loads during transport, assembly, or even during an earthquake, in comparison with normal operation.

The high clamping forces are transmitted by the clamping force element to a link of the bearing element to the module frame, said link comprising a foot part. The positioning of the module is effected by the positioning element, which is fixedly connected to the foot part. It is therefore only in the region of the very stiffly formed foot part that the force flow of the high clamping forces passes through the part of the bearing element which also determines the position of the module with respect to the module frame. The deformations caused by the high clamping forces in the connection of the module to the module frame will thus be minimized to the deformation of the very stiff foot part, whereby a deformation of an optical element mounted in the module can be advantageously minimized as well. The high clamping forces have the advantage that the connection of the foot part, which is in contact with the module frame only via one contact point, is also very stiff, whereby in the case where the module is an optical module of a projection exposure apparatus, the module can be excited only in frequency ranges which have little to no influence on the imaging quality of the projection exposure apparatus.

Furthermore, the division of the force flows traveling in the bearing element into a force flow pertaining to the clamping force and a force flow traveling via the positioning element and pertaining to the proportion of the weight force of the module, which is supported by the respective bearing element of the usually statically determined mounting of the module, can result in increased reproducibility in the context of module mounting. This can be advantageous especially when replacing the module at the customer's site, since positioning of the new module, which even in the case of an identical module may have different dimensions than the replaced module due to the manufacturing tolerances and mounting tolerances, is facilitated by the minimization of the non-reproducible deformations caused by the clamping force.

Furthermore, the clamping force element can have a receptacle for a clamping element of the clamping device. The clamping element can support itself on a base frame decoupled from the module frame, so that the reaction forces of the clamping forces cannot act on the module frame and unwanted deformations of the module can be advantageously avoided.

In addition, the positioning element can have a receptacle for the module, which in turn can have a linking surface for the module. The receptacle can be positioned via the positioning element independently of the receptacle for the clamping force element. The module can be screwed and/or adhesively bonded to the receptacle, although other connection techniques are also conceivable.

In a further embodiment, the bearing element can have at least one first spacer, i.e. a spacer produced to a predetermined thickness, such as for example a washer, for setting the linking surface for the module with respect to the module frame. This can be arranged between the foot part and a housing of the positioning element. For example, the foot part can be screwed to one end of the housing via a thread and the spacer can be designed in the form of a washer. The length of the positioning element and thus the position of the module with respect to the module frame in the direction of the longitudinal direction of the positioning element can be set by way of the thickness of the spacer. The clamping force element can be arranged in the housing of the positioning element, said housing being formed so as to be at least partly hollow, and can be connected to the foot part on the opposite side thereof relative to the module frame. As a result, the thickness of the spacer does not influence the position of the receptacle for the clamping element.

In particular, the bearing element can have at least one second spacer for setting the position of the receptacle for the clamping element with respect to a linking surface of the receptacle for the module. The distance between the receptacles can be expediently set during mounting of the bearing element such that a predetermined minimum distance is maintained even in the later positioning of the linking surface of the module with respect to the module frame and contact between the receptacles is avoided.

In addition, the clamping force element can have a rod between the receptacle for the clamping element and a link to the module. A rod is particularly well suited to transmitting a force along the longitudinal axis of the rod and is very stiff in this direction. The spacer for setting the distance between the receptacles can be arranged for example between the rod and the receptacle for the clamping element.

In a further embodiment, the clamping force element can be formed so as to be stiff only in its longitudinal direction, i.e. can be decoupled or flexible in all further degrees of freedom. In this context, stiff means that the stiffness of the clamping force element is designed to be as high as possible in the context of the design and the technical properties of the material used, such as for example yield strengths or flexural fatigue strengths. By contrast, flexible should be understood to mean a lowest possible stiffness in the context of the design and the technical properties of the material used.

In addition, the clamping force element and/or the positioning element can have at least one decoupling element. This can be formed for example as a monolithic joint, which can be produced by eroding and/or milling and/or other suitable manufacturing methods. The decoupling has the advantage that only forces in the longitudinal direction of the bearing element are transmitted and all further degrees of freedom are decoupled. The constraining forces on the bearing element that are possibly caused by manufacturing tolerances and/or assembly tolerances are minimized as a result.

In particular, the bearing element can have at least one end stop for protecting the at least one decoupling element in the clamping force element and/or the positioning element. These can prevent damage to the decoupling element, formed for example as a joint, which may be caused for example by the plastic deformation as a result of excessively great deflection.

In a further embodiment, a contact surface of the foot part can be formed so as to be convex. As a result, in the case of a module frame with a planar contact surface, the contact can be reduced to one well-defined contact point, which can be advantageous for reproducibility.

In particular, the radius of the convex contact surface can correspond to the distance between the contact surface and the decoupling between the rod and the receptacle for the clamping force element. As a result, parasitic constraining forces on the bearing element and thus also on the module that are caused by manufacturing tolerances and assembly tolerances can be advantageously avoided.

In a further embodiment, the clamping force element can be prestressed in relation to the foot part. The prestress can be realized for example by means of a compression spring arranged between the clamping force element and the positioning element. The prestress can ensure that the rod of the clamping force element is constantly in contact with the foot part.

Furthermore, the positioning element, only in its longitudinal direction, can be stiffly connected to the receptacle for the module and the link to the module. The other degrees of freedom can be decoupled, whereby, as already explained further above, advantageously parasitic forces on the module can be advantageously minimized or almost completely avoided.

In a further embodiment, the bearing element can have a spring for aligning the clamping force element with respect to the positioning element perpendicular to the clamping force. The spring can be formed at least in one direction perpendicular to the clamping force, which has the advantage that the positioning and the clamping act at least in one plane, whereby possible parasitic forces between the two elements of the bearing element can at least be minimized.

In particular, the assembly can comprise a bipod, i.e. a two-legged support, with two bearing elements. In this case, the spring can prevent the clamping force from departing from the plane spanned by the longitudinal directions of the two bearing elements aligned at an angle with respect to one another, whereby parasitic forces on the module can be advantageously minimized or almost completely avoided.

Furthermore, the bipod can comprise a decoupling element for decoupling a moment about an axis perpendicular to the longitudinal directions of the clamping force elements and the clamping force. The decoupling element can be formed for example as a joint, whereby the moment in the foot part caused by manufacturing tolerances and mounting tolerances during mounting of the bipod on the mounting frame can be advantageously minimized. The positioning element, which is crucial for the positioning and deformation of the module, is thus only subjected to by the minimized moment, and this can be further reduced by the decouplings formed in the positioning element.

In another aspect, disclosed is a device for semiconductor technology, for example a projection exposure apparatus or a mask inspection device, that includes an assembly according to any of the embodiments explained further above.

Other aspects, embodiments, and advantages follow.

### DESCRIPTION OF DRAWINGS

Exemplary embodiments and variants are explained in greater detail below with reference to the drawing, in which:

FIG. 1 schematically shows a meridional section of a projection exposure apparatus for EUV projection lithography,

FIG. 2 schematically shows a meridional section of a projection exposure apparatus for DUV projection lithography,

FIG. 3 shows a schematic illustration of an embodiment,

FIG. 4 shows one embodiment, and

FIG. 5 shows a view of a detail of one embodiment.

### DETAILED DESCRIPTION

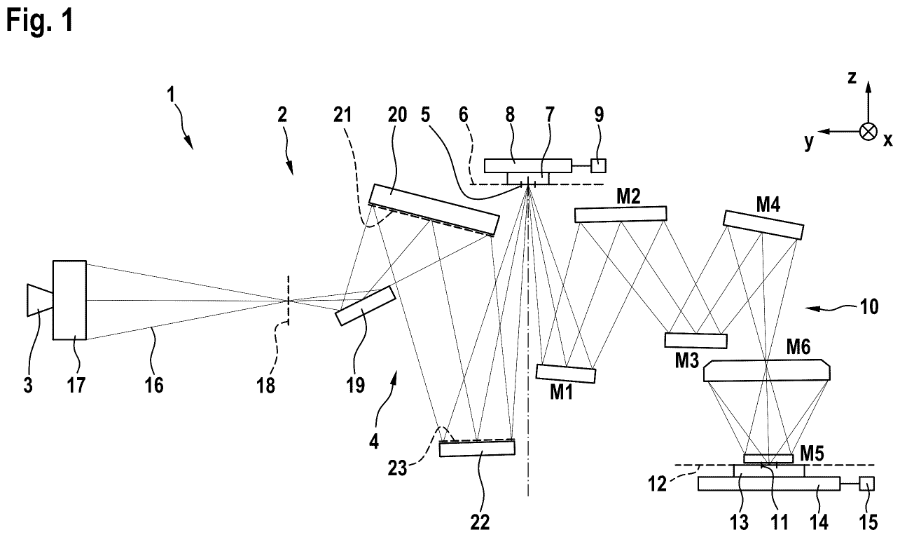

In the following text, the essential constituent parts of a microlithographic projection exposure apparatus 1 are described by way of example initially with reference to FIG. 1. The description of the fundamental setup of the projection exposure apparatus 1 and the constituent parts thereof are understood here to be non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9 in particular in a scanning direction.

A Cartesian xyz-coordinate system is depicted in FIG. 1 for explanation purposes. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15 in particular along the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits in particular EUV radiation 16, which is also referred to below as used radiation, illumination radiation or illumination light. The used radiation has in particular a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or with a plurality of ellipsoidal and/or hyperboloidal reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optics unit 4.

The illumination optics unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the pure deflection effect. Additionally or alternatively, the deflection mirror 19 can be embodied as a spectral filter that separates a used light wavelength of the illumination radiation 16 from extraneous light of a wavelength differing therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 can be embodied as macroscopic facets, in particular as rectangular facets or as facets with an arcuate or partly circular edge contour. The first facets 21 can be embodied as plane facets or alternatively as convexly or concavely curved facets.

As is known from DE 10 2008 009 600 A1, for example, the first facets 21 themselves can each also be composed of a multiplicity of individual mirrors, in particular a multiplicity of micromirrors. The first facet mirror 20 can be embodied in particular as a microelectromechanical system (MEMS system). For details, reference is made to DE 10 2008 009 600 A1.

Between the collector 17 and the deflection mirror 19, the illumination radiation 16 travels horizontally, i.e. along the y-direction.

In the beam path of the illumination optics unit 4, a second facet mirror 22 is disposed downstream of the first facet mirror 20. If the second facet mirror 22 is arranged in a pupil plane of the illumination optics unit 4, it is also referred to as a pupil facet mirror. The second facet mirror 22 can also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optics unit 4 thus forms a doubly faceted system. This basic principle is also referred to as a fly's eye condenser (fly's eye integrator).

It can be advantageous to arrange the second facet mirror 22 not exactly in a plane that is optically conjugate to a pupil plane of the projection optics unit 10. In particular, the pupil facet mirror 22 can be arranged so as to be tilted relative to a pupil plane of the projection optics unit 10, as described for example in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing in particular to the imaging of the first facets 21 into the object field 5 can be arranged in the beam path between the second facet mirror 22 and the object field 5. The transfer optics unit can have exactly one mirror, or alternatively two or more mirrors arranged one behind another in the beam path of the illumination optics unit 4. The transfer optics unit can in particular comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In a further embodiment of the illumination optics unit 4, the deflection mirror 19 can also be omitted, and so the illumination optics unit 4 can have exactly two mirrors downstream of the collector 17 in that case, specifically the first facet mirror 20 and the second facet mirror 22.

The imaging of the first facets 21 into the object plane 6 by means of the second facets 23 or using the second facets 23 and a transfer optics unit is regularly only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optics unit 10 is a doubly obscured optics unit. The projection optics unit 10 has an image-side numerical aperture that is greater than 0.5 and can also be greater than 0.6 and for example can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optics unit 4, the mirrors Mi can have highly reflective coatings for the illumination radiation 16. These coatings can be designed as multilayer coatings, in particular with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction can be of approximately the same magnitude as a z-distance between the object plane 6 and the image plane 12.

The projection optics unit 10 can be embodied in particular in anamorphic fashion. In particular, it has different imaging scales βx, βy in the x-and y-directions. The two imaging scales βx, βy of the projection optics unit 10 are preferably (βx, βy) =(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are likewise possible. Imaging scales with the same signs and the same absolute values in the x-and y-directions, for example with absolute values of 0.125 or 0.25, are also possible.

The number of intermediate image planes in the x-direction and in the y-direction in the beam path between the object field 5 and the image field 11 can be the same or can be different, depending on the embodiment of the projection optics unit 10. Examples of projection optics units with different numbers of such intermediate images in the x-and y-directions are known from US 2018/0074303 A1.

In each case one of the pupil facets 23 is assigned to exactly one of the field facets 21 for the purpose of forming a respective illumination channel for illuminating the object field 5. In particular, this can result in illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity can be achieved by overlaying different illumination channels.

The illumination of the entrance pupil of the projection optics unit 10 can be defined geometrically by way of an arrangement of the pupil facets. The intensity distribution in the entrance pupil of the projection optics unit 10 can be set by selecting the illumination channels, in particular the subset of the pupil facets that guide light. This intensity distribution is also referred to as illumination setting.

A likewise preferred pupil uniformity in the region of portions of an illumination pupil of the illumination optics unit 4 that are illuminated in a defined manner can be attained by a redistribution of the illumination channels.

Further aspects and details of the illumination of the object field 5 and in particular of the entrance pupil of the projection optics unit 10 are described below.

The projection optics unit 10 can have in particular a homocentric entrance pupil. The latter can be accessible. It can also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays that is determined in pairs becomes minimal. This area constitutes the entrance pupil or an area conjugate thereto in real space. In particular, this area exhibits a finite curvature.

It may be the case that the projection optics unit 10 has different poses of the entrance pupil for the tangential beam path and for the sagittal beam path. In this case, an imaging element, in particular an optical component of the transfer optics unit, should be provided between the second facet mirror 22 and the reticle 7. With the aid of this optical element, the different poses of the tangential entrance pupil and the sagittal entrance pupil can be taken into account.

In the arrangement of the components of the illumination optics unit 4 illustrated in FIG. 1, the pupil facet mirror 22 is arranged in an area conjugate to the entrance pupil of the projection optics unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

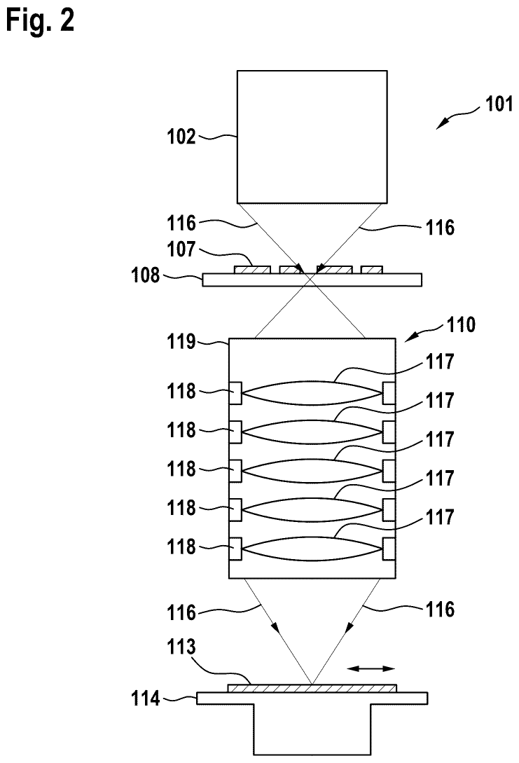

FIG. 2 schematically shows a meridional section through a further projection exposure apparatus 101 for DUV projection lithography, in which the embodiments can likewise be used.

The setup of the projection exposure apparatus 101 and the principle of the imaging are comparable with the setup and procedure described in FIG. 1. Identical component parts are denoted by a reference sign increased by 100 relative to FIG. 1, i.e. the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates and the like, can be used for imaging or for illumination in the DUV projection exposure apparatus 101 on account of the greater wavelength of the DUV radiation 116, employed as used light, in the range of 100 nm to 300 nm, in particular of 193 nm. The projection exposure apparatus 101 in this case essentially comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 by means of optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the setup of the downstream projection optics unit 101 with the lens housing 119 does not differ in principle from the setup described in FIG. 1 and is therefore not described in further detail.

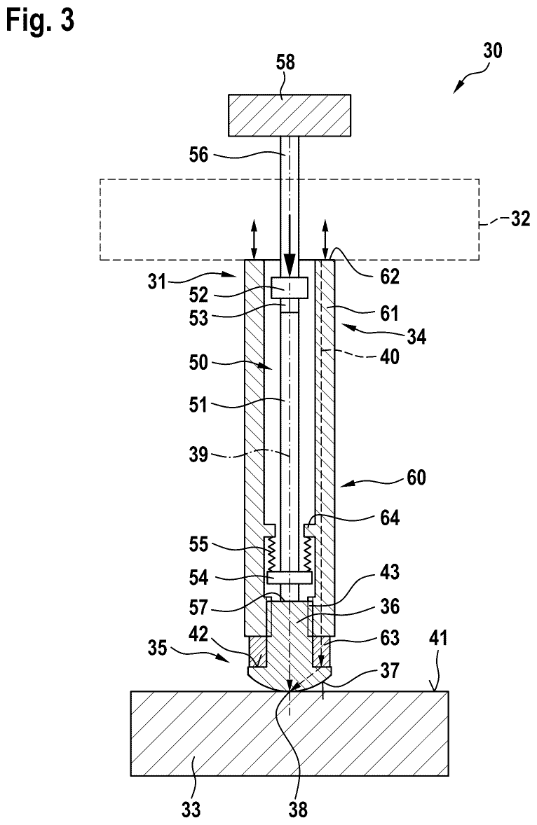

FIG. 3 shows a schematic illustration of an assembly 30, which is illustrated in a sectional view. The assembly 30 comprises a module 32, which comprises for example an optical element formed as a mirror Mx, 117, such as is used in one of the projection exposure apparatuses 1, 101 explained in FIG. 1 and FIG. 2. The module 32, which is illustrated as transparent and therefore with dashed lines in FIG. 3, is connected to a module frame 33 via a connection 31.

The connection 31 comprises a bearing element 34, via which the module 32 is mounted on the module frame 33, and a clamping element 56, which clamps the bearing element 34 between a base frame 58 and the module frame 33, so that lifting-off of the bearing element 34 and thus of the module 32, for example in the event of a shock load during transport, is reliably avoided.

The base frame 58 is decoupled from the module frame 33, so that the reaction forces of the clamping force do not act on the module frame 33. The clamping force caused by the clamping element 56 is illustrated as an arrow in FIG. 3 and acts on the clamping force element 50. The clamping force element 50 comprises a receptacle 52, via which the clamping element 56 transmits the clamping force to the clamping force element 50. The receptacle 52 is connected to a foot part 36 of the bearing element 34 via a rod 51, wherein the rod 51 is merely standing, i.e. is not fixedly connected, at the interface 57 between the rod 51 and the foot part 36.

A spacer 53 is arranged between the rod 51 and the receptacle 52, so that the length of the clamping force element 50 can be set by way of the spacer 53. The bearing element 34 further comprises a positioning element 60, which has a housing 61 with a linking surface 62 for the module 32. The foot part 36 is screwed to the housing 61 via a thread 43, wherein a spacer 63 is arranged between the head surface 42 of the foot part 36 and the underside of the housing 61. The thickness of the spacer 63 determines the position of the linking surface 62, whereby the module 32 can be positioned in the longitudinal direction of the bearing element 34. In the case of a customary static mounting of the module 32, six of the bearing elements 34 explained in FIG. 3, each of which can set one degree of freedom, are thus employed. Optionally, between the bearing element 34 and the module frame 33 it is also possible to arrange a further spacer (not illustrated) and/or to form a contact surface (not illustrated) separated from the bearing surface 41 of the module frame 33.

By means of a spring 55, which is supported on a projection 64 in the housing 61 of the positioning element 60 and presses against a shoulder 54 of the rod 51, the clamping force element 50 is prestressed in relation to the foot part 36 connected to the positioning element 60, so that the contact at the interface 57 between the rod 51 and the foot part 36, in particular when mounting the assembly 30, i.e. when for example the clamping element 56 has not yet been mounted, is always ensured. The force flow 39 of the clamping force travels via the clamping element 56, the receptacle 52, the spacer 53 and the rod 51 into the foot part 36, i.e. not through the housing 61 of the positioning element 60 used for positioning and receiving the module 32. This has the advantage that the high clamping force required only for transport or earthquake-induced load situations only acts on the foot part 36, which is also relevant to positioning, wherein a possibly resultant deformation of the common foot part 36 is minimal on account of the high stiffness thereof.

The clamping force additionally has a defined link via the contact point 38 between the contact surface 37 of the foot part 36 and the bearing surface 41 of the module frame 33, which link as a result likewise exerts a negligible influence on the positioning of the module 32. The force flow 40 through the positioning element 60 that comprises only the proportion of the weight force of the module 32 acting on the bearing element 34 travels via the housing 61, the spacer 63 and the foot part 36 into the module frame 33 and is illustrated as a dashed line in FIG. 3. The two force flows 39, 40 thus share only a minimal portion in the foot part 36, i.e. are almost independent of one another.

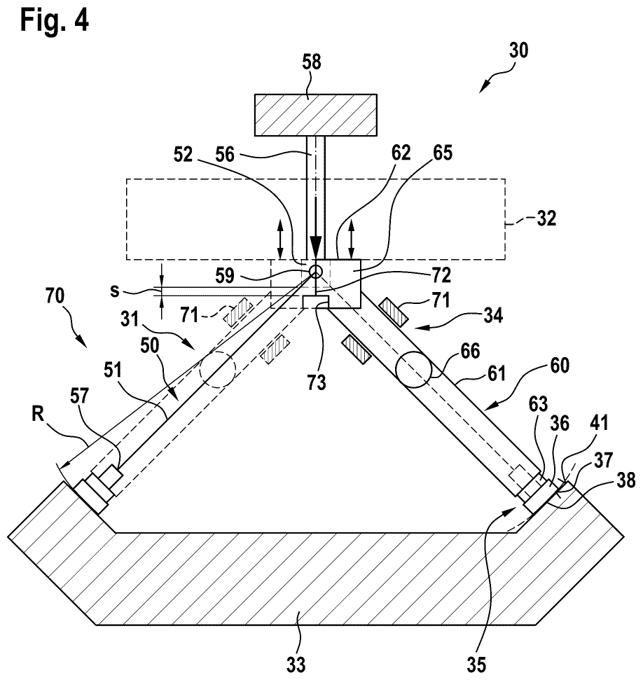

FIG. 4 shows a detail of one embodiment of an assembly 30, in which a bipod 70 with two bearing elements 34 is illustrated. The construction of the bearing elements 34 corresponds to that of the bearing elements 34 explained in FIG. 3. The two clamping force elements 50 of the bearing elements 34 are connected to one another in the receptacle 52 via a decoupling element formed as a joint 59, whereby the clamping force elements 50 in the plane of the drawing, during assembly, can be aligned with respect to one another independently of manufacturing and/or assembly tolerances, without a parasitic moment being introduced into the foot parts 36 of the bearing elements 34 and thereby via the positioning element 60 into the module 32. The contact surface 37 of the foot part 36 is formed so as to be convex, so that the foot part 36 and the bearing surface 41 of the module frame 33 are connected to one another via a contact point 38 independently of manufacturing tolerances and/or assembly tolerances. The radius R of the contact surface 37 corresponds to the distance between the joint 59 and the contact surface 37, whereby the connection is ensured at a contact point 38 and parasitic constraining forces caused by manufacturing and assembly tolerances are advantageously avoided. The housings 61 of the positioning elements 60 likewise comprise decoupling elements formed as joints 66, wherein the joints 66 are formed as universal joints with two axes formed perpendicular to one another and to the longitudinal axis of the housing 61.

The joints 66 decouple all manufacturing-related and assembly-related tolerances of the linking surface 62 of the receptacle 65 of the module 32, of the bearing elements 34 themselves and of the bearing surfaces 41 of the module frame 33. Furthermore, the bearing elements 34 have end stops 71, which protect the joints 66 from damage, for example a plastic deformation caused by excessively great deflection. The receptacle 52 for the clamping force elements 50 is centered with respect to the receptacle 65 of the positioning elements 50 in the direction perpendicular to the plane of the drawing by means of a spring formed as a pin 72, the spring being mounted in a receptacle 73 connected to the receptacle 65 for the module 32 of the positioning element 60, this ensuring that the force flow 39 of the clamping force elements 50 and the force flow 40 of the positioning elements 60 always travel at least in the plane of the drawing and ideally travel parallel to one another. As a result, the parasitic forces and moments on the module 32 are advantageously minimized.

The pin 72, in the region of the receptacles 52, 65, is the only connection between the positioning elements 60 and the clamping force elements 50, which are arranged spaced apart from one another in all further degrees of freedom. The distance s of the receptacles 52, 65 is influenced by the thickness of the spacers 63 for setting the position of the module 32 with respect to the module frame 33. The distance s is therefore expediently set during mounting of the bipods 70 by way of the spacers 53 explained in FIG. 3 between the receptacle 52 and the rod 51 of the clamping force elements 50 in such a way that the distance s does not fall below a minimum distance by virtue of the in the context of the typically occurring length changes of the positioning elements 60 required for positioning the module 32 at a predetermined position. The distance s is expediently set in such a way that the pin 72 does not at any time transmit forces in the direction of the clamping force, which is illustrated by an arrow in FIG. 4, but rather only causes a force for the centering of the two receptacles 52, 65.

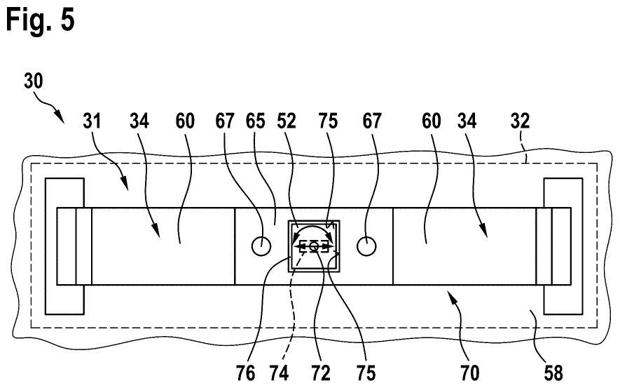

FIG. 5 shows a plan view of a detail of the assembly 30, illustrating a bipod 70. The module 32 is illustrated as transparent in FIG. 4 and therefore with dashed lines. Two linking points 67 for the module are arranged in the region of the receptacle 65 of the positioning elements 60. The receptacle 52 of the clamping force elements 50, which are concealed by the housings 61 of the positioning elements 60 in FIG. 5, is arranged in a cutout 76 of the receptacle 65, whereby the receptacle 52 can rotate about the axis of the pin 72 for centering the receptacle 52 with respect to the receptacle 65, as explained in FIG. 4, which is indicated by an arrow in FIG. 5. The receptacle 52 can also move freely in the direction of the projection of the longitudinal axes of the bearing elements 34 along a guide 74 of the pin 72. The edges of the cutout 76 in the receptacle 65 are formed as end stops 75 for the receptacle 52 in order to prevent plastic deformation of the joint 59 (FIG. 4).

Additional embodiments are within the scope of the following claims.

### List of Reference Signs

1 Projection exposure apparatus
2 Illumination system
3 Radiation source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Assembly
31 Connection
32 Module
33 Module frame
34 Bearing element
35 Link of bearing element
36 Foot part
37 Contact surface of foot part
38 Contact point of foot part
39 Force flow of clamping force
40 Force flow of positioning
41 Bearing surface of module frame
42 Head surface of foot part
43 Thread of foot part/housing
50 Clamping force element
51 Rod
52 Receptacle of clamping force element
53 Spacer of clamping force element
54 Shoulder
55 Prestress spring
56 Clamping element
57 Interface of rod and foot part
58 Base frame
59 Joint of rods linking to bipod
60 Positioning element
61 Housing
62 Linking surface of positioning element
63 Spacer
64 Projection
65 Receptacle of module
66 Joint of housing
67 Linking points of component
70 Bipod
71 End stop of housing
72 Pin
73 Receptacle of pin
74 Guide of pin
75 End stop of link of clamping element
76 Cutout
101 Projection exposure apparatus
102 Illumination system
107 Reticle
108 Reticle holder
110 Projection optics unit
113 Wafer
114 Wafer holder
116 DUV radiation
117 Optical element
118 Mounts
119 Lens housing
M1-M6 Mirror
R Radius of joint of link of clamping force element
s Distance between housing of positioning element and link of clamping force element

What is claimed is:

1. An assembly for semiconductor technology comprising a module and a module frame, wherein the module is connected to the module frame via a bearing element and is positioned by the bearing element with respect to the module frame and the connection comprises a clamping device, which prevents the module from lifting off the module frame,
wherein
the bearing element has a clamping force element for transmitting a clamping force caused by the clamping device and a positioning element for positioning the module with respect to the module frame, wherein the clamping force element is arranged within the positioning element.

2. The assembly of claim 1, wherein
the clamping force element has at least one receptacle for a clamping element of the clamping device.

3. The assembly of claim 1, wherein
the positioning element has at least one receptacle for the module.

4. The assembly of claim 1, wherein
the bearing element has at least one first spacer for setting the alignment of the module with respect to the module frame.

5. The assembly of claim 4, wherein
the bearing element has at least one second spacer for setting the position of the receptacle for the clamping element with respect to a linking surface of the receptacle for the module.

6. The assembly of claim 2, wherein
the clamping force element has a rod between the receptacle for the clamping element and a link to the module frame.

7. The assembly of claim 1, wherein
the clamping force element is formed so as to be stiff only in its longitudinal direction.

8. The assembly of claim 1, wherein
the clamping force element and/or the positioning element have/has at least one decoupling element.

9. The assembly of claim 8, wherein
the bearing element has at least one end stop for protecting the at least one decoupling element in the clamping force element and/or the positioning element.

10. The assembly of claim 6, wherein
a contact surface of the link of the bearing element to the module frame is formed so as to be convex.

11. The assembly of claim 10, wherein
the radius (R) of the convex contact surface corresponds to the distance between the contact surface and the decoupling between the rod and the receptacle of the clamping force element.

12. The assembly of claim 6, wherein
the clamping force element is prestressed in relation to the link to the module frame.

13. The assembly of claim 6, wherein
the positioning element, only in its longitudinal direction, is stiffly connected to the receptacle for the module and the link to the module frame.

14. The assembly of claim 1, wherein
the bearing element has a spring for aligning the clamping force element with respect to the positioning element perpendicular to the clamping force.

15. The assembly of claim 1, wherein
the assembly comprises a bipod with two bearing elements.

16. The assembly of claim 15, wherein
the bipod comprises a decoupling element for decoupling a moment about an axis perpendicular to the longitudinal directions of the clamping force elements and perpendicular to the clamping force.

17. A device for semiconductor technology comprising an assembly of claim 1.

18. The device of claim 17, wherein
the device is a projection exposure apparatus.

19. The device of claim 17, wherein
the device is a mask inspection device.
